(19) United States
(12) Patent Application Publication
(10) Pub. No.: US 2024/0098927 A1
(43) Pub. Date: Mar. 21, 2024

(54) ELECTRICAL DEVICE, INVERTER, ELECTRIC DRIVE, VEHICLE AND MANUFACTURING METHODS

(71) Applicant: Valeo eAutomotive Germany GmbH, Erlangen (DE)

(72) Inventors: Alexandros KOURGIALIS, Erlangen (DE); Anna KAISER, Erlangen (DE); Michael NOBEL, Erlangen (DE); Michael TILP, Erlangen (DE)

(73) Assignee: Valeo eAutomotive Germany GmbH, Erlangen (DE)

(21) Appl. No.: 18/254,271

(22) PCT Filed: Oct. 27, 2021
(86) PCT No.: PCT/EP2021/079825

§ 371 Date: May 24, 2023

(30) Foreign Application Priority Data
Dec. 7, 2020 (DE) 10 2020 215 434.1

(51) Int. Cl. H05K 7/14; B60L 15/00; G01R 15/20; H05K 1/18

(52) U.S. Cl. CPC H05K 7/14324; B60L 15/007; G01R 15/202; H05K 1/184; H05K 2201/10151

(57) ABSTRACT

Electrical device including a printed circuit board, a sensor mounted on the printed circuit board and projecting from the PCB, and a sensor protection component including a housing in which is housed the sensor.

The present invention relates to an electrical device, as well as an inverter, an electric drive and a vehicle comprising such electrical device, and manufacturing methods. It is especially intended be used in an automotive vehicle.

Current measurement in an electrical conductor may be accomplished by using a so-called shunt design. However, such a shunt design requires an electrical connection with the conductor.

An object of the invention is to allow to measure electrical current in a non-intrusive manner, while still obtaining precise measurements.

The object of the invention may be solved by an electrical device comprising:
a printed circuit board,
a sensor mounted on said printed circuit board and projecting from the printed circuit board, and
a sensor protection component comprising a housing in which is housed the sensor.

The sensor is preferably an Hall Sensor. Thanks to the use of the Hall sensor, a non-intrusive measure may be carried out by introducing a portion of the Hall sensor sensitive to magnetic field into the air gap of a magnetic core surrounding the conductor. However, this requires at least this magnetic field sensitive portion of the hall sensor to be precisely placed in the air gap, and preferably in the middle of this air gap. Due to the size of the magnetic core and possibly other design constraints, the PCB may be located at a long distance from the air gap, and more particularly from the middle of the air gap. The Hall sensor must therefore extends over a long distance from the PCB to the air gap, which may lead to a very elongated Hall sensor. This may prevent the use of a SMD (Surface Mounted Device) component, which are rarely elongated, in favor of a Hall sensor having a body at a distance from the printed circuit board, abbreviated as PCB, and connection pins connecting the body to the PCB. Because of its elongated shape, the Hall sensor could be bent during handling and assembling, so that the magnetic field sensitive portion could be misplaced in the air gap. This may happen particularly when using a Hall sensor with connection pins, since those pins may have a very small diameter and therefore may be easily bent. The sensor protection component may help to overcome this problem by the fact that the Hall sensor is housed in the housing of the sensor protection component, which may protected the Hall sensor from mechanical stress and bending during e.g. handling and assembling, in particular when the Hall sensor is introduced into the air gap.

Some further optional features of the invention which can be used together or separately are developed below.

The sensor protection component may be mounted and fixed on the PCB.

The sensor, in particular the Hall sensor may comprises a body and at least one connection pin projecting from the body and connected to the PCB so that the body extends at a distance from the PCB.

The sensor, in particular the Hall sensor may be mounted on the PCB by through-hole technology.

The sensor protection component may comprise at least one positioning pin extending through the PCB and allowing the positioning of said sensor protection component on the PCB.

The sensor protection component may comprise at least one snap fits extending through the PCB and fixing said sensor protection component on the PCB.

The housing of the sensor protection component may comprise a first opening facing the PCB, said first opening having a frustoconical shape allowing for centering the sensors, in particular the Hall sensors when entering said housing.

The invention also relates to an inverter comprising:
input terminals,
output terminals,
controllable switches connected to the input terminals and to the output terminals, and
an electrical device as described above, configured to control the controllable switches so as to convert a DC voltage at the input terminals into an AC voltage at the output terminals.

Preferably, the inverter comprises a magnetic core around one of the output terminals, said magnetic core being provided with an air gap, and the sensor, in particular the Hall sensor may extend in the air gap.

The invention also relates to an electric drive comprising an inverter as described above and an electric motor driven by the inverter.

The invention also relates to a vehicle comprising wheels and an electric drive as described above for driving, at least indirectly, at least one of the wheels.

The invention also relates to a method for manufacturing an electrical device as described above, comprising:
mounting a sensor, in particular a Hall sensor on a printed circuit board, and
mounting a sensor protection component on the printed circuit board by positioning the sensor, in particular the Hall sensor inside a housing of the sensor protection component.

The invention also relates to a method for manufacturing an inverter, comprising:
manufacturing a power module comprising input terminals, output terminals, and controllable switches connected to the input terminals and to the output terminals,
manufacturing, as described above, an electrical device being a control device of the power module,
mounting a magnetic core provided with an air gap around at least one of the output terminals,
mounting the electrical device on the power module, so that the sensor, in particular the Hall sensor extends in the air gap of the magnetic core, and
connecting the electrical device to the power module to control the controllable switches so as to convert a DC voltage at the input terminals into an AC voltage at the output terminals.

The present invention will be described more specifically with reference to the following drawings, in which:

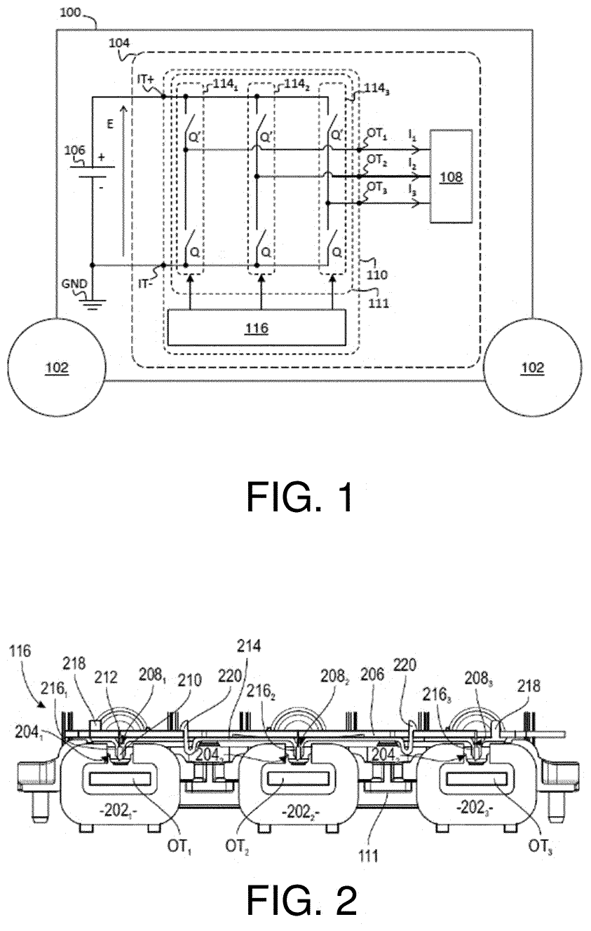

FIG. 1 is a schematic view showing an embodiment of a vehicle comprising an inverter with an electric control device according to the invention,

FIG. 2 is a sectional view of the inverter of FIG. 1,

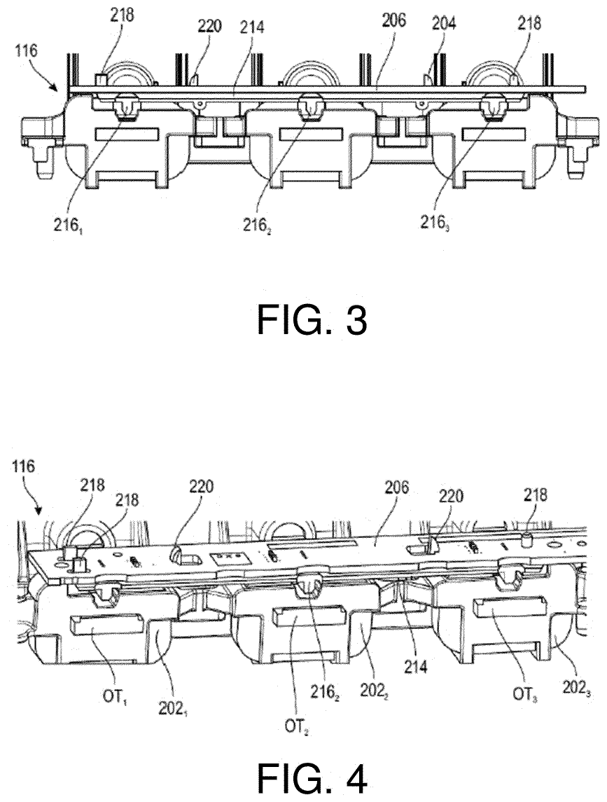

FIG. 3 is a front/section view of the inverter of FIGS. 1 and 2,

FIG. 4 is a 3D section/view of the inverter of FIGS. 1 to 3,

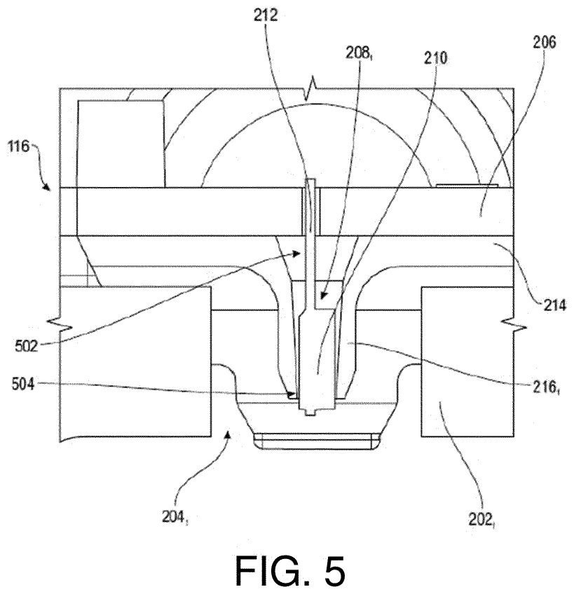

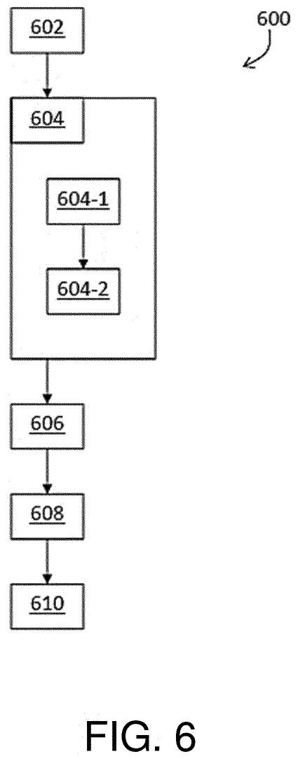

FIG. 5 is a zoom in on a Hall effect sensor of the control device projection view of FIGS. 1 to 4, and

FIG. 6 is a block diagram illustrating a method for manufacturing the inverter of FIGS. 1 to 5.

Referring to FIG. 1, a vehicle 100 according to the invention will now be described. In the described example, the vehicle 100 is an automotive vehicle.

The vehicle 100 comprises wheels 102 and an electric drive 104 configured to drive at least one of the wheels 102 at least indirectly. The vehicle 100 further comprises a DC voltage source 106, such as a battery, for electrically powering the electric drive 104. The DC voltage source 106 is configured to provide a DC voltage E.

The electric drive 104 comprises a motor, for instance, an electric asynchronous motor 108 and an inverter 110 configured to drive the motor 108, for instance by supplying electric power. For example, the motor 108 is a rotary electric motor comprising a stator and a rotor configured to rotate around a rotation axis with respect to the stator.

The stator is provided with stator phases. In the described example, the motor 108 is a three-phase electric motor comprising three stator phases.

The inverter 110 is intended to drive the motor 108 so that phase currents I₁₋₃ flows respectively in the stator phases, so as to produce a rotating magnetic field rotating around the rotation axis.

The inverter 110 comprises input terminals IT+, IT− connected to the DC voltage source 106 so that the DC voltage E is present at the input terminals IT+, IT−. More precisely, the input terminals IT+, IT− include a positive input terminal IT+ connected to a positive terminal of the DC voltage source 106 and a negative input terminal IT− connected to a negative terminal of the DC voltage source 106 and to an electrical ground GND.

The inverter 110 further comprises output terminals OT₁₋₃ connected to the motor 108. An AC voltage is intended to be present at the output terminals OT₁₋₃ for powering the electric motor 108. More precisely, the output terminals OT₁₋₃ are connected to respective stator phase of the motor 108 and the respective phase currents I₁₋₃ are intended to flow through them. The AC voltage may be a single or a multiphase AC voltage. In the described example where the motor 108 is a three-phase electric motor, the AC voltage is a three-phase AC voltage.

The inverter 110 further comprises a power module 111 including controllable switches Q, Q′, called main switches, connected to the input terminals IT+, IT− and to the output terminals OT. The main switches Q, Q′ may be semi-conductor switches comprising for example transistors. Each main switch Q, Q′ comprises for example one amongst: a Metal Oxide Semiconductor Field Effect Transistor (MOSFET), an Insulated Gate Bipolar Transistor (IGBT) and a Silicon Carbide MOSFET (SiC MOSFET).

In the described example, the power module 111 comprises switch legs 114₁₋₃ respectively associated to the stator phases of the motor 108. Each switch leg 114₁₋₃ comprises a high side (HS) main switch Q′ connected to the positive input terminal IT+ and a low side (LS) main switch Q connected to the negative input terminal IT−. The HS main switch Q′ and the LS main switch Q are connected to each other at a middle point connected to the output terminal OT connected to the associated stator phase of the motor 108.

Each switch leg 114₁₋₃ is intended to be controlled to commute between two configurations. In the first one, called high side (HS) configuration, the HS main switch Q′ is closed (on) and the LS main switch Q is open (off) so that the DC voltage E is essentially applied to the associated stator phase. In the second one, called low side (LS) configuration, the HS main switch Q′ is open (off) and the LS main switch Q is closed (on) so that a zero voltage is essentially applied to the associated stator phase.

The inverter 110 further comprises a control device 116 configured to control the power module 111, and, more precisely, the main switches Q, Q′ such that the main switches Q, Q′ convert the DC voltage E into the AC voltage. In the described example, the control device 116 is configured to commute each switch leg 114 between the two configurations mentioned above.

For controlling the power module 111, the control device 116 uses at least one measured phase current I₁₋₃.

Referring to FIGS. 2 to 5, an example of a system for measuring the phase current I₁₋₃ will now be described.

The electric drive 104 comprises, for at least one of the output terminals OT₁₋₃, a magnetic core 202₁₋₃ mounted around this output terminal OT₁₋₃. In the described example, all three output terminals OT₁₋₃ are associated with a respective magnetic core 202₁₋₃. Each magnetic core 202₁₋₃ comprises an air gap 204₁₋₃. When the phase currents I₁₋₃ flow through the output terminals OT₁₋₃, they create respective magnetic fields in the magnetic cores 202₁₋₃ which pass through the air gaps 204₁₋₃. These magnetic fields are therefore representative of the phase currents I₁₋₃.

To measure the magnetic fields and determine from them the phase currents I₁₋₃, the control device 116 comprises a printed circuit board 206, herein called PCB, on which sensors, in particular Hall sensors 208₁₋₃ are mounted, one for each measured phase currents I₁₋₃.

More precisely, in the described example, each Hall sensor 208₁₋₃ comprises a body 210 and at least one connection pin 212 (three in the described example) projecting from the body 210. The connection pins 212 are connected to the PCB 206 so that the body 210 extends at a distance from the PCB 206, in the air gap 204₁₋₃ of the respective magnetic core 202₁₋₃.

Each Hall sensor 208₁₋₃ is for example mounted on the PCB 206 using Through Hole Technology (THT). Advantageously, the connection pins 212 of the Hall sensor 208₁₋₃ are soldered to the PCB 206.

In order to accurately measure the magnetic field, the body 210 of each Hall sensor 208₁₋₃ needs to be precisely positioned in the respective air gap 204₁₋₃, for example precisely in the middle of the air gap 204₁₋₃.

However, the PCB 206 is located at a distance from the air gap 204₁₋₃, so that the connection pins 212 need to be long. Because of this length, the connection pins 212 are prone to bending so that the positioning of the body 210 may become incorrect, which in turn could have a negative functional impact.

To overcome this problem, the control device 116 also comprises a sensor protection component 214 intended to protect the sensors 208₁₋₃ from mechanical stress and bending in particular during handling and assembly operations. The sensor protection component 214 comprises, for each sensor 208₁₋₃, a housing 216₁₋₃ in which this sensor 208₁₋₃ is housed. Advantageously, the sensor protection component 214 comprises a plurality of housings 216₁₋₃, for example three housings in the described example, for respectively receiving the plurality of sensors 208₁₋₃. In particular, the body 210 of the sensor 208₁₋₃ is held in place by the housing 216₁₋₃. To this end, the body 210 is preferably in contact with at least to walls of the housing 216₁₋₃ facing each other.

The sensor protection component 214 is preferentially made in one single piece, for example in plastic.

Once mounted on the PCB 206, the sensor protection component 214 is in abutment against a lower face of the PCB 206. Advantageously, the sensor protection component 214 comprises at least on positioning pin 218 for positioning the sensor protection component 201 relative to the PCB 206 during mounting, and at least one snap fit 220 for fixing the sensor protection component 214 to the PCB 206. When the sensor protection component 214 is mounted on the PCB 206, the positioning pin 218 as well as the snap fit 220 extend through the PCB 206. The mounting of the sensor protection component 214 is better represented on FIG. 4.

When the Hall sensor 208₁₋₃ is housed in the housing 216₁₋₃ of the sensor protection component 214, the risks of bending and damaging the Hall sensor 208₁₋₃ are considerably reduced. Furthermore, the positioning of the Hall sensor 208₁₋₃ may be controlled relative to the magnetic core 202₁₋₃, allowing a good current measure.

Referring more particularly to FIG. 5, in the described embodiment, each housing 216₁₋₃ of the sensor protection component 214 comprises a first opening 502 facing the PCB 206. The first opening 502 has a frustoconical shape. This shape allows to center the respective Hall sensor 208₁₋₃ when entering said housing 216₁₋₃. Each housings 216₁₋₃ of the sensor protection component 214 may also comprises a lower opening 504, opposite to the first opening 502. An extremity of the Hall sensor 210 preferably passes through said lower opening 504. In is also possible that the entire Hall sensor is covered by the protection component 214 preferably made from plastics.

Referring to FIG. 6, an example of a method 600 for manufacturing the inverter 110 will now be described. In other embodiments, the order of the steps could differ.

At a step 602, the power module 111 is manufactured. As explained above, the power module 111 comprises the input terminals IT+, IT−, the output terminals OT₁, OT₂, OT₃, and the controllable switches Q, Q′ connected to the input terminals IT+, IT− and to the output terminals OT₁, OT₂, OT₃.

At a step 604, the control device 116 is manufactured. This step comprises in particular the following steps.

At a step 604-1, each Hall sensor 208₁₋₃ is mounted on the PCB 206. For example, the connection pins 212 of each Hall sensor 208₁₋₃ are passed into corresponding holes of the PCB 206 and soldered to the PCB 206.

At a step 604-2, the sensor protection component 214 is mounted on the PCB 206, for positioning the Hall sensors 208₁₋₃ inside their respective housings 216₁₋₃ of the sensor protection component 214. For example, the step 604-2 comprises positioning said sensor protection component 214 in abutment with the PCB 206) by inserting the positioning pins 218 of the sensor protection component 214 through the PCB 206, and fixing the sensor protection component 214 to the PCB 206 by inserting the snap fits 220 of the sensor protection component 214 through the PCB 206.

At a step 606 or preferably at step 602, the magnetic cores 202₁₋₃ are respectively mounted around the output terminals OT₁₋₃.

At a step 608, the control device 116 is mounted on the power module 111, so that the Hall sensors 208₁₋₃, extends in the air gap 204₁₋₃ of the respective magnetic core 202₁₋₃.

At a step 610, the control device 116 is connected to the power module 111 to control the controllable switches Q, Q′ so as to convert a DC voltage at the input terminals IT+, IT− into an AC voltage at the output terminals OT₁₋₃.

It will be noted that the invention is not limited to the embodiments described above. It will indeed appear to those skilled in the art that various modifications can be made to the embodiments described above, in the light of the teaching which has just been disclosed.

In the previous detailed description of the invention, the terms used should not be interpreted as limiting the invention to the embodiments presented in the present description, but should be interpreted to include all the equivalents within the reach of those skilled in the art by applying their general knowledge to the implementation of the teaching which has just been disclosed.

1. Electrical device comprising:
a printed circuit board,
a sensor mounted on said printed circuit board and projecting from the printed circuit board, and
a sensor protection component comprising a housing in which is housed the sensor.

2. Electrical device according to claim 1, wherein the sensor is a Hall sensor, and/or the protection component is mounted and fixed on the printed circuit board.

3. Electrical device according to claim 1, wherein the sensor comprises a body and at least one connection pin projecting from the body and connected to the PCB so that the body extends at a distance from the printed circuit board.

4. Electrical device according to claim 1, wherein the sensor is mounted on the printed circuit board by through-hole technology.

5. Electrical device according to claim 1, wherein the sensor protection component comprises at least one pin extending through the printed circuit board and allowing the positioning of said sensor protection component on the printed circuit board.

6. Electrical device according to claim 1, wherein the sensor protection component comprises at least one snap fits extending through the printed circuit board and fixing said sensor protection component on the printed circuit board.

7. Electrical device according to claim 1, wherein the housing of the sensor protection component comprises an opening facing the printed circuit board, said opening having a frustoconical shape allowing for centering the Hall sensor when entering said housing.

8. Inverter comprising:
input terminals,
output terminals,
controllable switches connected to the input terminals and to the output terminals, and
an electrical device according to claim 1, configured to control the controllable switches so as to convert a DC voltage at the input terminals into an AC voltage at the output terminals.

9. Inverter according to claim 8, further comprising a magnetic core around one of the output terminals, OTA said magnetic core being provided with an air gap, and wherein the Hall sensor extends in the air gap.

10. Electric drive comprising an inverter according to claim 8, and an electric motor driven by the inverter.

11. Vehicle comprising wheels and an electric drive according to claim 10 for driving, at least indirectly, at least one of the wheels.

12. Method for manufacturing an electrical device, particularly according to claim 1, comprising:
mounting a sensor, in particular Hall sensor on a printed circuit board, and
mounting a sensor protection component on the printed circuit board for positioning the sensor inside a housing of the sensor protection component.

13. Method for manufacturing an inverter, comprising:
manufacturing a power module comprising input terminals, output terminals, and controllable switches connected to the input terminals and to the output terminals,
manufacturing, according to claim 12, an electrical device being a control device of the power module,
mounting a magnetic core provided with an air gap around at least one of the output terminals,
mounting the electrical device on the power module, so that the sensor extends in the air gap of the magnetic core, and
connecting the control device to the power module to control the controllable switches so as to convert a DC voltage at the input terminals into an AC voltage at the output terminals.

14. Electrical device according to claim 2, wherein the sensor comprises a body and at least one connection pin projecting from the body and connected to the PCB so that the body extends at a distance from the printed circuit board.

15. Electrical device according to claim 2, wherein the sensor is mounted on the printed circuit board by through-hole technology.

16. Electrical device according to claim 2, wherein the sensor protection component comprises at least one pin extending through the printed circuit board and allowing the positioning of said sensor protection component on the printed circuit board.

17. Electrical device according to claim 2, wherein the sensor protection component comprises at least one snap fits extending through the printed circuit board and fixing said sensor protection component on the printed circuit board.

18. Electrical device according to claim 2, wherein the housing of the sensor protection component comprises an opening facing the printed circuit board, said opening having a frustoconical shape allowing for centering the Hall sensor when entering said housing.

19. Inverter comprising:
input terminals,
output terminals,
controllable switches connected to the input terminals and to the output terminals, and
an electrical device according to claim 2, configured to control the controllable switches so as to convert a DC voltage at the input terminals into an AC voltage at the output terminals.

20. Electric drive comprising an inverter according to claim 9, and an electric motor driven by the inverter.
